(19) United States
(12) Patent Application Publication
(10) Pub. No.: US 2026/0282331 A1
(43) Pub. Date: Sep. 17, 2026

(54) MEMORY AND MANUFACTURING METHOD THEREFOR, AND ELECTRONIC DEVICE

(71) Applicant: BEIJING SUPERSTRING ACADEMY OF MEMORY TECHNOLOGY, Beijing (CN)

(72) Inventors: Xuezheng Ai, Beijing (CN); Xiangsheng Wang, Beijing (CN); Guilei Wang, Beijing (CN); Chao Zhao, Beijing (CN); Jin Dai, Beijing (CN); Wenhua Gui, Beijing (CN); Wei Yu, Beijing (CN)

(73) Assignee: BEIJING SUPERSTRING ACADEMY OF MEMORY TECHNOLOGY, Beijing (CN)

(21) Appl. No.: 19/167,216

(22) PCT Filed: Apr. 28, 2023
(86) PCT No.: PCT/CN2023/091747

§ 371 Date: Sep. 19, 2025

(30) Foreign Application Priority Data
Mar. 28, 2023 (CN) 202310314393.2

(51) Int. Cl. H10B 12/00; H10D 1/68

(52) U.S. Cl. CPC H10B 12/482; H10B 12/03; H10B 12/05; H10B 12/488; H10D 1/714

(57) ABSTRACT

A memory and a manufacturing method therefor, and an electronic device are disclosed. The memory includes transistors, word lines, and bit lines. The word line extends in a direction perpendicular to a substrate. The transistors each include a semiconductor layer located on a sidewall of the word line, and a gate insulating layer arranged between the sidewall of the word line and the semiconductor layer. The bit line includes a bit line main body, and a plurality of first branches corresponding to the plurality of transistors, respectively. The bit line body extends in a first direction parallel to the substrate. The first branches extend towards the semiconductor layer and are connected to the semiconductor layer.

### CROSS-REFERENCE TO RELATED APPLICATIONS

The present disclosure claims priority to Chinese patent application No. 202310314393.2, titled “MEMORY AND MANUFACTURING METHOD THEREFOR, AND ELECTRONIC DEVICE”, filed with China national intellectual property administration on Mar. 28, 2023, the entire content of which is incorporated herein by reference.

### TECHNICAL FIELD

The present disclosure relates to the field of semiconductor technologies, and in particular, to a memory and manufacturing method therefor, and an electronic device.

### BACKGROUND

With the development of communication technology and digital technology, people are constantly pursuing products with lower power consumption, lighter weight and better performance. Three-dimensional dynamic random access memory (3D-DRAM) can have higher integration density and larger storage capacity, and has gradually become one of the important research fields of memory. However, the conventional manufacturing process currently available for manufacturing 3D-DRAM is prone to generate large parasitic capacitance in the 3D-DRAM, resulting in introduction of noise, thereby affecting the further improvement of the structure and performance of the 3D-DRAM.

### SUMMARY

Embodiments of the present disclosure provide a memory and manufacturing method therefor, and an electronic device.

According to some embodiments, the present disclosure provides a memory. The memory includes a word line, transistors and a bit line. The word line extends in a direction perpendicular to a substrate. The transistors each includes a semiconductor layer located on a sidewall of the word line, and a gate insulating layer arranged between the sidewall of the word line and the semiconductor layer. The bit line includes a bit line body and different first branches corresponding to different transistors. The bit line body extends in a first direction parallel to the substrate, and the first branches extend towards the semiconductor layer and are connected to the semiconductor layer.

According to some embodiments, the bit line includes two first branches corresponding to a same transistor, and a first receiving cavity is formed between the two first branches, the bit line body and the gate insulating layer. The memory further includes a first insulating layer filled in the first receiving cavity.

According to some embodiments, the first branches and the bit line body are formed by patterning a single conductive film layer. The first branches and the bit line body have a same film thickness, and the film thickness is a dimension in the direction perpendicular to the substrate.

According to some embodiments, the semiconductor layer includes two sub-film layers extending along the sidewall of the word line, respectively. The two sub-film layers are spaced apart in the first direction, and the two sub-film layers are connected to the two first branches in a one-to-one correspondence.

According to some embodiments, the memory further includes a capacitor. The capacitor includes a first electrode connected to the semiconductor layer. The first electrode includes two second branches. The two second branches are connected to the two sub-film layers of the semiconductor layer in a one-to-one correspondence.

According to some embodiments, the first electrode further includes a first electrode body connected to the two second branches. The first electrode body and the second branches are sequentially arranged in a second direction, and the second direction is parallel to the substrate and intersects the first direction. A second receiving cavity is formed between the first electrode body, the two second branches and the gate insulating layer. The memory further includes a second insulating layer filled in the second receiving cavity.

According to some embodiments, the capacitor further includes a second electrode arranged between the first electrode and the second insulating layer, and a first dielectric layer surrounding a sidewall of the second electrode.

According to some embodiments, the capacitor further includes a second dielectric layer and a third electrode stacked on an outer surface of the first electrode. The third electrode is connected to the second electrode.

According to some embodiments, there is a plurality of transistors. The plurality of transistors are distributed in one layer, or distributed in different layers stacked in the direction perpendicular to the substrate.

According to some embodiments, another aspect of the present disclosure further provides a manufacturing method for a memory, including the following steps.

A conductive film layer is formed on a substrate.

The conductive film layer is patterned to form a bit line. The bit line includes a bit line body extending in a first direction parallel to the substrate, and a plurality of first branches spaced apart in the first direction.

A transistor and a word line are formed correspondingly at extended end portions of two adjacent first branches. The word line extends in a direction perpendicular to the substrate. The transistor includes a semiconductor layer located on a sidewall of the word line, and a gate insulating layer arranged between the sidewall of the word line and the semiconductor layer. The plurality of first branches extend towards the semiconductor layer and are connected to the semiconductor layer.

According to some embodiments, a first receiving cavity is formed between two first branches corresponding to a same transistor, the bit line body and the gate insulating layer. The manufacturing method further includes: filling the first receiving cavity with an insulating material to form a first insulating layer.

According to some embodiments, the memory further includes a capacitor including a first electrode. The manufacturing method further includes: forming the first electrode simultaneously with the bit line when patterning the conductive film layer. The first electrode includes two second branches spaced apart in the first direction. The semiconductor layer is further connected to the two second branches.

According to some embodiments, the first electrode further includes a first electrode body connected to the two second branches. The first electrode body and the second branches are sequentially arranged in a second direction parallel to the substrate, and a second receiving cavity is formed between the first electrode body, the two second branches and the gate insulating layer. The manufacturing method further includes: filling the second receiving cavity with an insulating material to form a second insulating layer.

According to some embodiments, forming the transistor and the word line correspondingly at the extended end portions of two adjacent first branches includes the following steps.

A sacrificial material is filled in a region between the first electrode body, the two second branches, the two first branches, and the bit line body before forming the first insulating layer and the second insulating layer.

A part of the sacrificial material is removed to form a receiving hole. The receiving hole is configured to define a formation region of the transistor and the word line.

An initial semiconductor layer, the gate insulating layer and the word line are formed sequentially on an inner wall of the receiving hole.

A remaining part of the sacrificial material is removed to expose a first sidewall of the initial semiconductor layer facing the first electrode and a second sidewall of the initial semiconductor layer facing the bit line.

The initial semiconductor layer based on the first sidewall and the second sidewall is etched until the gate insulating layer is exposed, and a remaining part of the initial semiconductor layer is made to form two sub-film layers spaced apart in the first direction. Both ends of each sub-film layer are connected to the corresponding first branch and second branch, respectively.

According to some embodiments, the manufacturing method further includes: forming a second electrode and a first dielectric layer surrounding a sidewall of the second electrode between the first electrode and the second insulating layer.

According to some embodiments, the manufacturing method further includes: forming a second dielectric layer on an outer surface of the first electrode while forming the first dielectric layer between the first electrode and the second insulating layer; and forming a third electrode on an outer surface of the second dielectric layer, and connecting the third electrode to the second electrode while forming the second electrode between the first electrode and the second insulating layer.

According to some embodiments, a further aspect of the present disclosure further provides a memory, including: a conductive film layer, a gate, a semiconductor layer and a gate insulating layer. The conductive film layer includes a bit line region extending in a column direction, and a source region and a drain region sequentially distributed towards the bit line region in a row direction. The drain region is connected to the bit line region. The source region and the drain region are spaced apart. The gate is located between the source region and the drain region, and extends in a direction perpendicular to a substrate. The semiconductor layer is arranged on a sidewall of the gate. The gate insulating layer is arranged between the sidewall of the gate and the semiconductor layer. At least one of the source region or the drain region includes two third branches, and the two third branches are each connected to the semiconductor layer.

According to some embodiments, the third branches and the bit line region have a same film thickness, and the film thickness is a dimension in a direction perpendicular to the substrate.

According to some embodiments, the semiconductor layer includes two sub-regions spaced apart, the two sub-regions extend in the row direction on the sidewall of the gate, and an extended end portion of any of the two sub-regions is connected to an extended end portion of the corresponding third branch of the source region or the drain region.

According to some embodiments, the conductive film layer further includes a first electrode region. The first electrode region, the source region and the drain region are sequentially distributed towards the bit line region in the row direction, and the first electrode region is connected to the source region.

According to some embodiments, the source region includes two third branches. The first electrode region includes two second branches. The two second branches are connected to the two third branches of the source region in a one-to-one correspondence.

According to some embodiments, a further aspect of the present disclosure provides an electronic device, including the memory as described in any of the above embodiments.

One or more embodiments of the present disclosure will be described in detail below with reference to drawings. Other features, objects and advantages of the present disclosure will become more apparent from the description, drawings, and claims.

### BRIEF DESCRIPTION OF THE DRAWINGS

In order to describe the technical solutions in the embodiments of the present disclosure more clearly, the following briefly introduces the accompanying drawings required for describing the embodiments. Apparently, the accompanying drawings, in the following description, illustrate merely some embodiments of the present disclosure, for a person of ordinary skill in the art, drawings of other embodiments can also be obtained according to these accompanying drawings without making any creative efforts.

FIG. 1 is a schematic diagram showing a structure of a memory according to some embodiments, FIG. 1a is a schematic cross-sectional view of the memory shown in FIG. 1 at a section C1, FIG. 1b is a schematic cross-sectional view of the memory shown in FIG. 1 at a section C2, and FIG. 1c is a schematic cross-sectional view of the memory shown in FIG. 1 at a section C3.

FIG. 2 is a schematic flow diagram of a manufacturing method for a memory according to some embodiments.

FIG. 3 is a schematic flow diagram of another manufacturing method for a memory according to some embodiments.

FIG. 4 is a schematic flow diagram of the step 30 according to some embodiments.

FIG. 5 is a schematic diagram showing a structure obtained after forming a first mask layer in some embodiments, FIG. 5a is a schematic cross-sectional view of the structure shown in FIG. 5 at a section C1, FIG. 5b is a schematic cross-sectional view of the structure shown in FIG. 5 at a section C2, and FIG. 5c is a schematic cross-sectional view of the structure shown in FIG. 5 at a section C3.

FIG. 6 is a schematic diagram showing a structure obtained after forming an isolation layer in some embodiments, FIG. 6a is a schematic cross-sectional view of the structure shown in FIG. 6 at a section C1, FIG. 6b is a schematic cross-sectional view of the structure shown in FIG. 6 at a section C2, and FIG. 6c is a schematic cross-sectional view of the structure shown in FIG. 6 at a section C3.

FIG. 7 is a schematic diagram showing a structure obtained after forming a second sacrificial layer in some embodiments, FIG. 7a is a schematic cross-sectional view of the structure shown in FIG. 7 at a section C1, FIG. 7b is a schematic cross-sectional view of the structure shown in FIG. 7 at a section C2, and FIG. 7c is a schematic cross-sectional view of the structure shown in FIG. 7 at a section C3.

FIG. 8 is a schematic diagram showing a structure obtained after exposing a first electrode in some embodiments, FIG. 8a is a schematic cross-sectional view of the structure shown in FIG. 8 at a section C1, FIG. 8b is a schematic cross-sectional view of the structure shown in FIG. 8 at a C4 section, and FIG. 8c is a schematic cross-sectional view of the structure shown in FIG. 8 at a section C3.

FIG. 9 is a schematic diagram showing a structure obtained after forming a capacitor in some embodiments, FIG. 9a is a schematic cross-sectional view of the structure shown in FIG. 9 at a section C1, FIG. 9b is a schematic cross-sectional view of the structure shown in FIG. 9 at a C4 section, and FIG. 9c is a schematic cross-sectional view of the structure shown in FIG. 9 at a section C3.

FIG. 10 is a schematic diagram showing a structure obtained after forming a receiving hole in some embodiments, FIG. 10a is a schematic cross-sectional view of the structure shown in FIG. 10 at a section C1, FIG. 10b is a schematic cross-sectional view of the structure shown in FIG. 10 at a section C2, and FIG. 10c is a schematic cross-sectional view of the structure shown in FIG. 10 at a section C3.

FIG. 11 is a schematic diagram showing a structure obtained after forming a word line in some embodiments, FIG. 11a is a schematic cross-sectional view of the structure shown in FIG. 11 at a section C1, FIG. 11b is a schematic cross-sectional view of the structure shown in FIG. 11 at a section C2, and FIG. 11c is a schematic cross-sectional view of the structure shown in FIG. 11 at a section C3.

FIG. 12 is a schematic diagram showing a structure obtained after forming a sub-film layer of a semiconductor layer in some embodiments, FIG. 12a is a schematic cross-sectional view of the structure shown in FIG. 12 at a section C1, FIG. 12b is a schematic cross-sectional view of the structure shown in FIG. 12 at a section C2, and FIG. 12c is a schematic cross-sectional view of the structure shown in FIG. 12 at a section C3.

FIG. 13 is a schematic diagram showing a structure of another memory according to some embodiments, FIG. 13a is a schematic cross-sectional view of the memory shown in FIG. 13 at a section C1, FIG. 13b is a schematic cross-sectional view of the memory shown in FIG. 13 at a section C2, and FIG. 13c is a schematic cross-sectional view of the memory shown in FIG. 13 at a section C3.

### DETAILED DESCRIPTION OF THE EMBODIMENTS

In order to facilitate understanding of the present disclosure, the present disclosure will be described more fully below with reference to the relevant accompanying drawings. Embodiments of the present disclosure are illustrated in the accompanying drawings. However, the present disclosure may be implemented in many different forms and is not limited to the embodiments described herein. Rather, these embodiments are provided for the purpose of making the present disclosure more thorough and comprehensive.

Unless otherwise defined, all technical and scientific terms used herein have the same meaning as commonly understood by a person of ordinary skill in the art to which the present disclosure belongs. The terms used herein in the specification of the present disclosure are merely intended to describe specific embodiments, and are not intended to limit the present disclosure.

It should be understood that when an element or layer is referred to as being “on”, “adjacent”, “connected to”, or “coupled to” another element or layer, it can be directly on, adjacent to, connected to, or coupled to the other element or layer, or intervening elements or layers may also be present. In contrast, when an element is referred to as being “directly on”, “directly adjacent to”, “directly connected”, or “directly coupled to” another element or layer, there are no intervening elements or layers present.

Spatially relative terms, such as “under”, “below”, “lower”, “beneath”, “over”, “upper” and the like, may be used herein to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements or features described as “below” or “under” or “beneath” other elements or features would be oriented “above” the other elements or features. Thus, the exemplary term “below” and “under” can encompass both an orientation of over and under. In addition, the device may be otherwise oriented (rotated 90 degrees or at other orientations), and the spatially relative descriptors used herein interpreted accordingly.

As used herein, the singular forms “a”, “an” and “the” can also include the plural forms, unless the context clearly indicates otherwise. It will be further understood that the terms “includes/comprises” or “has” and the like specify the presence of stated features, integers, steps, operations, components, parts or combinations thereof, but do not preclude the presence or addition of one or more other features, integers, steps, operations, components, parts or combinations thereof. Meanwhile, in this description, the term “and/or” includes any and all combinations of the associated listed items.

Embodiments of the present disclosure are described herein with reference to cross-sectional views of schematic diagrams of ideal embodiments (and intermediate structures) of the present disclosure, so that variations in the shape shown due to, for example, manufacturing techniques and/or tolerances, can be expected. Accordingly, the embodiments of the present disclosure should not be limited to the particular shapes of regions illustrated herein but are to include deviations in shapes that result, for example, from manufacturing techniques. The regions shown in the figures are substantially schematic and their shapes do not indicate the actual shape of the region of the device and do not limit the scope of the present disclosure.

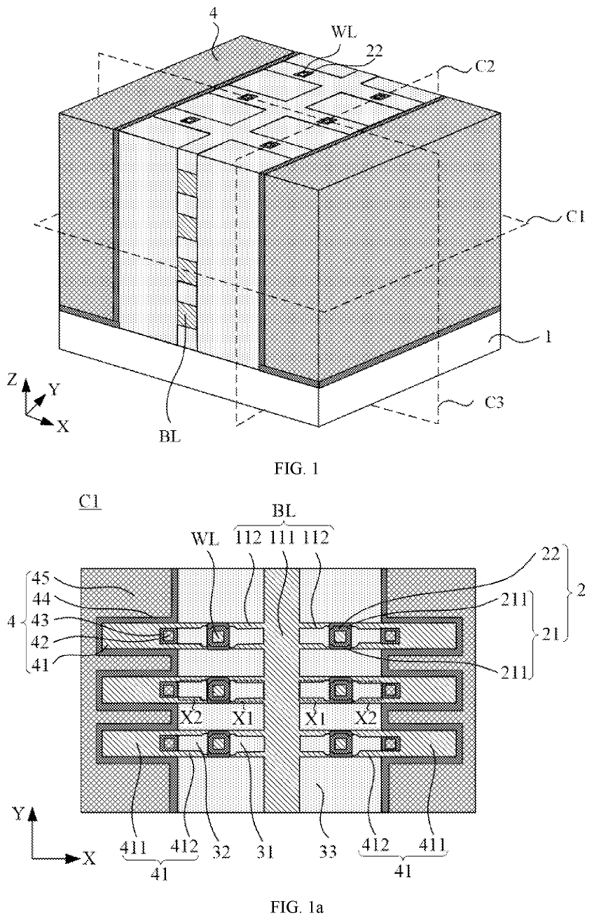

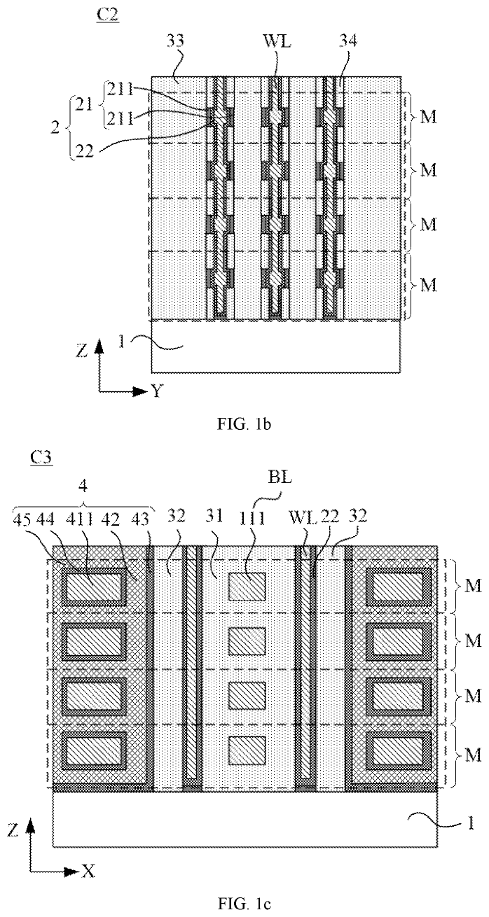

Some embodiments of the present disclosure provide a memory. Referring to FIGS. 1, 1a, 1b, and 1c, the memory includes word lines WL, transistors 2, and bit lines BL. The word line WL extends in a direction perpendicular to a substrate 1 (e.g., Z direction). The transistors 2 each include a semiconductor layer 21 located on or surrounding a sidewall of the word line WL and a gate insulating layer 22 arranged between the sidewall of the word line WL and the semiconductor layer 21. The bit line BL includes a bit line body 111 and different first branches 112 corresponding to different transistors 2. The bit line body 111 extends in a first direction (e.g., Y direction) parallel to the substrate 1. The first branches 112 extend towards the semiconductor layer 21 and are connected to the semiconductor layer 21.

The semiconductor layer 21 surrounds the word line WL, which may be understood as not completely surrounding the word line WL, but surrounding a part of the sidewall of the word line WL. For example, the semiconductor layer 21 has portions spaced apart from each other in a lateral direction and not physically connected. For example, the semiconductor layer 21 extends in a direction perpendicular to the sidewall of the word line WL and in a direction parallel to the extension of the first branches 112, and the semiconductor layer 21 is not arranged between two adjacent first branches 112 belonging to the same transistor 2.

In some embodiments, the memory includes one or more memory layers M stacked in the direction perpendicular to the substrate 1 (e.g., Z direction). Accordingly, there is a plurality of transistors 2. The plurality of transistors 2 may be distributed in a single memory layer M. Alternatively, the plurality of transistors 2 may be distributed in different memory layers M stacked in the direction perpendicular to the substrate 1.

Exemplarily, the substrate 1 may be made of a semiconductor material, an insulating material, a conductive material or any combination of these materials. The substrate 1 may be a single-layer structure or a multi-layer structure. For example, the substrate 1 may be a silicon (Si) substrate, a silicon germanium (SiGe) substrate, a silicon germanium carbon (SiGeC) substrate, a silicon carbide (SiC) substrate, a gallium arsenide (GaAs) substrate, an indium arsenide (InAs) substrate, an indium phosphide (InP) substrate or other III/V semiconductor substrates or II/VI semiconductor substrates. Alternatively, the substrate 1 may be a layered substrate including, for example, a stack of Si and SiGe, a stack of Si and SiC, a silicon-on-insulator (SOI), or a silicon-germanium-on-insulator, or the like.

Exemplarily, each transistor 2 in each memory layer M may be taken as a transistor of a corresponding memory cell, and the memory cell may be of a 1T1C, 1T0C or 2T0C architecture. Taking the 1T1C architecture as an example, the memory cell may include a capacitor and a transistor connected to the capacitor. Exemplarily, in a 3D-DRAM, a plurality of memory cells may be distributed in arrays in planes parallel to the substrate 1 (e.g., X-Y plane), and these arrays of memory cells are stacked periodically in the direction perpendicular to the substrate 1 (e.g., Z direction) to form multiple storage layers M.

In some embodiments, with reference to FIG. 1a, FIG. 1a shows an embodiment in which two columns of memory cells share a bit line BL. In the memory layer M, the bit line BL is parallel to the substrate 1 and extends in the Y direction. A plurality of transistors 2 may be arranged in the Y direction on both sides of the corresponding bit line BL, thereby achieving the arrangement of the memory cells on both sides of the corresponding bit line BL (it can be understood that the transistors 2 are arranged in two regions divided by the bit line BL).

In some embodiments, as shown in FIG. 1a, the number of the first branches 112 in the bit line BL corresponding to a same transistor 2 is two, and a first receiving cavity X1 is formed between the two first branches 112, the bit line body 111 and the gate insulating layer 22. The memory further includes a first insulating layer 31 filled in the first receiving cavity X1.

Exemplarily, the first insulating layer 31 includes, but is not limited to, a silicon oxide layer.

In the embodiments of the present disclosure, the bit line BL includes the bit line body 111 and different first branches 112 corresponding to different transistors 2, and the first branches 112 extend towards the semiconductor layer 21 of the corresponding transistor 2 and are connected to the semiconductor layer 21. The first insulating layer 31 may be provided by using the first receiving cavity X1 formed between the first branches 112, the bit line body 111 and the gate insulating layer 22. As a result, the isolation effect between the word line WL and the bit line BL is effectively improved, and a large area between the bit line BL and the semiconductor layer 21 is avoided to minimize the parasitic capacitance. Thus, the memory performance can be further improved.

In some embodiments, referring to FIG. 1a, the first branches 112 and the bit line body 111 are formed by patterning a conductive film layer. The first branches 112 and the bit line body 111 have the same film thickness, and the film thickness is a dimension in the direction perpendicular to the substrate 1 (e.g., Z direction).

The first branches 112 of the bit line BL and the bit line body 111 are formed through a process of patterning the same conductive film layer, which is beneficial to simplifying the manufacturing process of the memory to improve the production efficiency.

Exemplarily, the conductive film layer may be a metal layer, such as a tungsten metal layer or a copper metal layer.

In some embodiments, referring to FIG. 1 a and FIG. 1b, the semiconductor layer 21 includes two sub-film layers 211 extending along the sidewall of the word line WL, respectively. The two sub-film layers 211 are spaced apart in the first direction, and the two sub-film layers 211 are connected to the two first branches 112 in a one-to-one correspondence.

The semiconductor layer 21 may at least serve as a channel layer of the transistor 2 in the corresponding memory cell.

Exemplarily, the sub-film layer 211 in the semiconductor layer 21 may be a metal oxide semiconductor layer, for example, a metal oxide semiconductor material including at least one of indium, gallium, zinc or tin.

In some examples, the sub-film layer 211 in the semiconductor layer 21 may be an indium gallium zinc oxide (IGZO) layer, but is not limited thereto.

In addition, the word line WL described above is a gate word line, and can be used as the word line WL of the memory and also used as a gate of the transistor 2 in the corresponding memory cell, thereby controlling the transistor 2 to be turned on or off.

Exemplarily, the material of the word line WL includes metal, such as tungsten or copper.

Exemplarily, a shape of an orthographic projection of the word line WL on a surface of the substrate 1 includes but is not limited to a rectangle. The rectangle described here may be an ideal rectangle having right-angled corners, or an approximate rectangle including an etching deviation or a transition corner.

Exemplarily, the gate insulating layer 22 includes, but is not limited to, a HK dielectric layer.

It should be noted that, from the memory layers M, the semiconductor layers 21 arranged adjacent to each other in the direction perpendicular to the substrate 1 may be manufactured by etching the same initial semiconductor layer, and the corresponding manufacturing method is described later in the specification. The embodiments of the present disclosure can minimize unnecessary semiconductor materials between a capacitor 4 and the bit line BL to minimize the parasitic capacitance, thereby further optimizing the memory performance.

In some embodiments, referring to FIG. 1, FIG. la and FIG. 1c, the memory further includes a capacitor 4. The capacitor 4 includes a first electrode 41 connected to the semiconductor layer 21. The first electrode 41 includes a first electrode body 411 and two second branches 412. The two second branches 412 are connected to the two sub-film layers 211 of the semiconductor layer 21 in a one-to-one correspondence.

In some embodiments, referring to FIG. 1a and FIG. 1c, the first electrode body 411 in the first electrode 41 is connected to the two second branches 412. The first electrode body 411 and the second branches 412 are sequentially arranged in a second direction (e.g., X direction). The second direction (e.g., X direction) is parallel to the substrate 1 and intersects the first direction (e.g., Y direction). A second receiving cavity X2 is formed between the first electrode body 411, the two second branches 412 and the gate insulating layer 22. The memory further includes a second insulating layer 32 filled in the second receiving cavity X2.

Exemplarily, the second insulating layer 32 includes, but is not limited to, a silicon oxide layer.

In the embodiments of the present disclosure, the first electrode 41 includes the first electrode body 411 and the two second branches 412, and the second branches 412 extend towards the semiconductor layer 21 of the transistor 2 and are connected to the semiconductor layer 21. The second insulating layer 32 may be provided by using the second receiving cavity X2 formed between the second branches 412, the first electrode body 411 and the gate insulating layer 22. As a result, the isolation effect between the word line WL and the first electrode 41 of the capacitor 4 is effectively improved, and a large face-to-face area between the first electrode 41 of the capacitor 4 and the semiconductor layer 21 is avoided to minimize the parasitic capacitance, thereby further improving the memory performance.

In some embodiments, referring to FIG. 1a and FIG. 1c, the capacitor 4 further includes a second electrode 42 arranged between the first electrode 41 and the second insulating layer 32, and a first dielectric layer 43 surrounding a sidewall of the second electrode 42.

Exemplarily, a shape of an orthographic projection of the second electrode 42 on the surface of the substrate 1 includes but is not limited to a rectangle. The rectangle described here may be an ideal rectangle having right-angled corners, or an approximate rectangle including an etching deviation or a transition corner.

In some embodiments, referring to FIG. 1a and FIG. 1c, the capacitor 4 further includes a second dielectric layer 44 and a third electrode 45 stacked on an outer surface of the first electrode 41. The third electrode 45 is connected to the second electrode 42.

Exemplarily, the first dielectric layer 43 and the second dielectric layer 44 may be formed of a same dielectric material and by a same deposition process.

Exemplarily, the first dielectric layer 43 and the second dielectric layer 44 include, but are not limited to, HK (high-K) dielectric layers. The HK dielectric layer refers to a dielectric layer with a high dielectric constant K. The high dielectric constant K is, for example, greater than 3.9.

In addition, the deposition process described above and below includes but is not limited to an atomic layer deposition (ALD) process, a chemical vapor deposition (CVD) process, a molecular layer deposition (MLD) process, or the like.

Exemplarily, the second electrode 42 and the third electrode 45 may be formed of a same conductive material and by a same deposition process.

Exemplarily, the second electrode 42 and the third electrode 45 include but are not limited to polysilicon.

It should be noted that, referring to FIG. 1 and FIG. 1a, FIG. 1c, in the same memory layer M in some embodiments, a plurality of second dielectric layers 44 of a column of capacitors 4 arranged in the first direction (e.g., Y direction) may be connected as a whole, and a plurality of third electrodes 45 of the column of capacitors 4 may be connected as a whole. Furthermore, in different memory layers M in some embodiments, a plurality of third electrodes 45 of the capacitors 4 located on the same side of the bit line BL may be connected as a whole.

Furthermore, optionally, in different memory layers M in some embodiments, as shown in FIG. 1c, the first dielectric layers 43 of the capacitors 4 arranged adjacent to each other in the direction perpendicular to the substrate 1 (e.g., Z direction) are connected as a whole.

Optionally, as shown in FIG. 1c, in the memory layer M adjacent to the substrate 1, the first dielectric layer 43 further extends between the third electrode 45 and the substrate 1.

It is worth mentioning that, in order to match the arrangement of the conductive elements (such as the bit line BL, the word line WL, the first electrode 41, the second electrode 42 and the third electrode 45) in the above-described memory, the memory may further include other insulating layers in addition to the first insulating layer 31 and the second insulating layer 32, such as a third insulating layer 33 and a fourth insulating layer 34 in FIG. 1b, so as to meet the insulation requirement between adjacent conductive elements or between the conductive elements and the outside, which will not be discussed in detail in the embodiments of the present disclosure.

In some embodiments of the present disclosure, a manufacturing method for a memory is provided, which is configured to manufacture the memory in the embodiments as described above. This manufacturing method also possesses the technical advantages of the above-described memory.

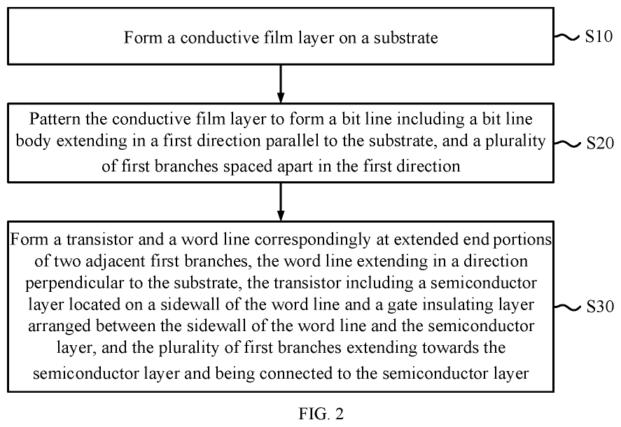

Referring to FIG. 2 and in combination with FIG. 1, FIG. 1a, FIG. 1b and FIG. 1c, it is understood that the manufacturing method includes the following steps.

In step S10, a conductive film layer is formed on a substrate 1.

In step S20, the conductive film layer is patterned to form a bit line BL. The bit line BL includes a bit line body 111 extending in a first direction (e.g., Y direction) parallel to the substrate 1, and a plurality of first branches 112 spaced apart in the first direction (e.g., Y direction).

In step S30, a transistor 2 and a word line WL are formed correspondingly at extended end portions of two adjacent first branches 112. The word line WL extends in a direction perpendicular to the substrate 1 (e.g., Z direction), the transistor 2 includes a semiconductor layer 21 located on a sidewall of the word line WL and a gate insulating layer 22 arranged between the sidewall of the word line WL and the semiconductor layer 21, and the plurality of first branches 112 extend towards the semiconductor layer 21 and are connected to the semiconductor layer 21.

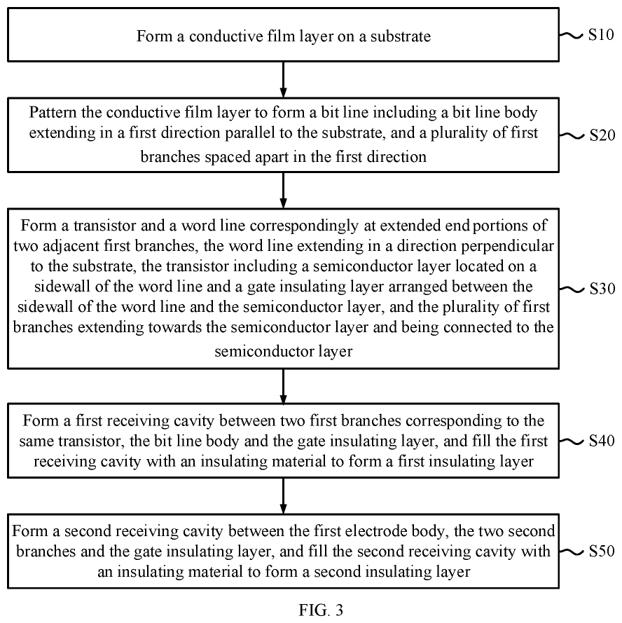

In some embodiments, as shown in FIG. 1a, a first receiving cavity X1 is formed between two first branches 211 corresponding to the same transistor 2, the bit line body 111 and the gate insulating layer 22. Referring to FIG. 3 and in combination with FIG. 1a, it is understood that the manufacturing method further includes step S40.

In step S40, the first receiving cavity X1 is filled with an insulating material to form a first insulating layer 31.

In some embodiments, with reference to FIG. 1, FIG. 1a and FIG. 1c, it is understood that the memory further includes a capacitor 4. The capacitor 4 includes a first electrode 41. The manufacturing method further includes: forming the first electrode 41 simultaneously with the bit line BL when patterning the conductive film layer. The first electrode 41 includes two second branches 412 spaced apart in the first direction (e.g., the Y direction). The semiconductor layer 21 is further connected to the two second branches 412 correspondingly.

In some embodiments, with reference to FIG. 1, FIG. 1a and FIG. 1c, it is understood that the first electrode 41 further includes a first electrode body 411 connected to the two second branches 412. The first electrode body 411 and the second branches 412 are sequentially arranged in a second direction (e.g., X direction) parallel to the substrate 1, and a second receiving cavity X2 is formed between the first electrode body 411, the two second branches 412 and the gate insulating layer 22. Referring to FIG. 3 and in combination with FIG. 1a, it is understood that the manufacturing method further includes step S50.

In step S50, the second receiving cavity X2 is filled with an insulating material to form a second insulating layer 32.

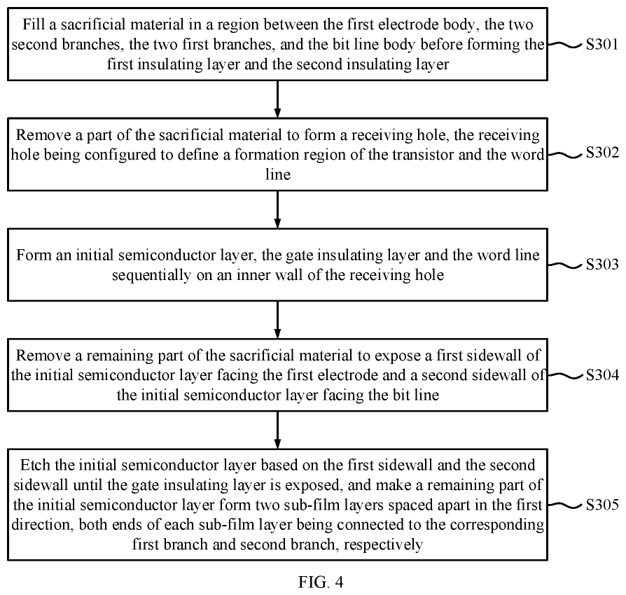

In some embodiments, referring to FIG. 4 and in combination with FIG. 1, FIG. 1a, FIG. 1b and FIG. 1c, it is understood that the step S30 of forming the transistor 2 and the word line WL correspondingly at the extended end portions of two adjacent first branches 112 includes but is not limited to the following steps.

In step S301, before forming the first insulating layer 31 and the second insulating layer 32, a sacrificial material is filled in a region between the first electrode body 411, the two second branches 412, the two first branches 112, and the bit line body 111.

In step S302, a part of the sacrificial material is removed to form a receiving hole. The receiving hole is configured to define a formation region of the transistor 2 and the word line WL.

In step S303, an initial semiconductor layer, the gate insulating layer 22 and the word line WL are formed sequentially on an inner wall of the receiving hole.

In step S304, a remaining part of the sacrificial material is removed to expose a first sidewall of the initial semiconductor layer facing the first electrode 41 and a second sidewall of the initial semiconductor layer facing the bit line BL.

In step S305, the initial semiconductor layer is etched on the first sidewall and the second sidewall until the gate insulating layer 22 is exposed, a remaining part of the initial semiconductor layer is made to form two sub-film layers 211 spaced apart in the first direction (e.g., Y direction), and both ends of each sub-film layer 211 are connected to the corresponding first branch 112 and second branch 412, respectively.

In some embodiments, with reference to FIG. 1, FIG. 1a and FIG. 1c, the manufacturing method further includes step S60.

In step S60, a second electrode 42 and a first dielectric layer 43 surrounding a sidewall of the second electrode 42 are formed between the first electrode 41 and the second insulating layer 32.

In some embodiments, with reference to FIG. 1, FIG. 1a, and FIG. 1c, it is understood that the manufacturing method further includes steps S601 and S602.

In step S601, a second dielectric layer 44 is formed on an outer surface of the first electrode 41, while forming the first dielectric layer 43 between the first electrode 41 and the second insulating layer 32.

In step S602, a third electrode 45 is formed on an outer surface of the second dielectric layer 44, and the third electrode 45 is connected to the second electrode 42, while forming the second electrode 42 between the first electrode 41 and the second insulating layer 32.

It can be understood that although some steps in the manufacturing method for the memory as described above are shown sequentially as indicated by arrows in FIGS. 2, 3 and 4, the steps are not necessarily performed sequentially in the order indicated by the arrows. Unless explicitly stated herein, the performing of these steps is not strictly limited in any order and these steps can be performed in any other order. Moreover, at least some of the steps in FIGS. 2, 3 and 4 may include multiple sub-steps or multiple stages that are not necessarily performed simultaneously, but may be performed at different moments. The order in which these sub-steps or stages are performed is not necessarily sequential, and these sub-steps or stages may be performed in turn or alternately with at least some of other steps or at least some of sub-steps or stages in other steps.

In order to more clearly illustrate the manufacturing method for the memory in the embodiments as described above, some of the following embodiments exemplarily provide some possible specific implementations of some steps.

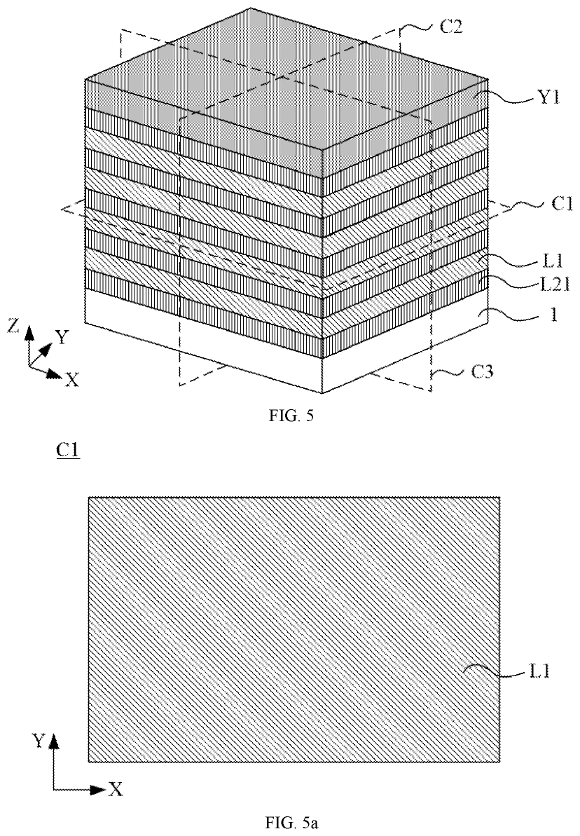

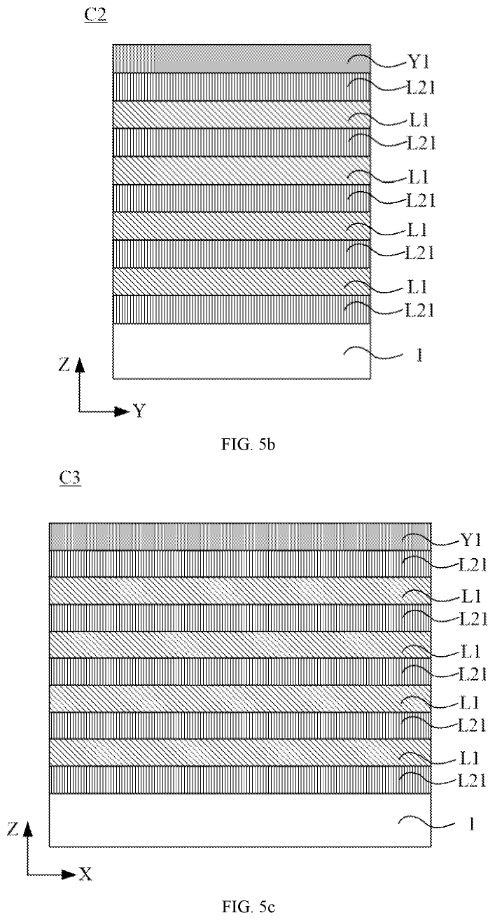

In step S10, referring to FIG. 5 and FIG. 5a, FIG. 5b, and FIG. 5c, a plurality of conductive film layers L1 and a plurality of first sacrificial layers L21 stacked and alternately distributed in the direction perpendicular to the substrate 1 (e.g., Z direction) are formed.

Exemplarily, the substrate 1 may be made of semiconductor material, insulating material, conductive material or any combination of these materials. The substrate 1 may be a single-layer structure or a multi-layer structure. For example, the substrate 1 may be a silicon (Si) substrate, a silicon germanium (SiGe) substrate, a silicon germanium carbon (SiGeC) substrate, a silicon carbide (SiC) substrate, a gallium arsenide (GaAs) substrate, an indium arsenide (InAs) substrate, an indium phosphide (InP) substrate or other III/V semiconductor substrates or II/VI semiconductor substrates. Alternatively, the substrate 1 may be a layered substrate including, for example, a stack of Si and SiGe, a stack of Si and SiC, a silicon-on-insulator (SOI), or a silicon-germanium-on-insulator, or the like.

Exemplarily, the conductive film layer L1 includes a metal layer, such as a tungsten metal layer.

Exemplarily, the first sacrificial layer L21 includes, but is not limited to, a silicon nitride layer.

The number of stacked conductive film layers L1 may be set according to a number of stacked memory layers M in the memory. Furthermore, the first sacrificial layer L21 may be located between adjacent conductive film layers L1 or on a side of the first and last conductive film layers L1, and a number of first sacrificial layers L21 may match the number of stacked conductive film layers L1. Each conductive film layer L1 and each first sacrificial layer L21 can be formed by using a deposition process.

In addition, after the plurality of alternately stacked conductive film layers L1 and first sacrificial layers L21 are formed, a first mask layer Y1, such as a photoresist layer and/or a hard mask layer, may be formed on an upper surface of the top first sacrificial layer L21, so as to facilitate the subsequent etching of the conductive film layers L1 and the first sacrificial layers L21 based on a mask pattern in the first mask layer Y1.

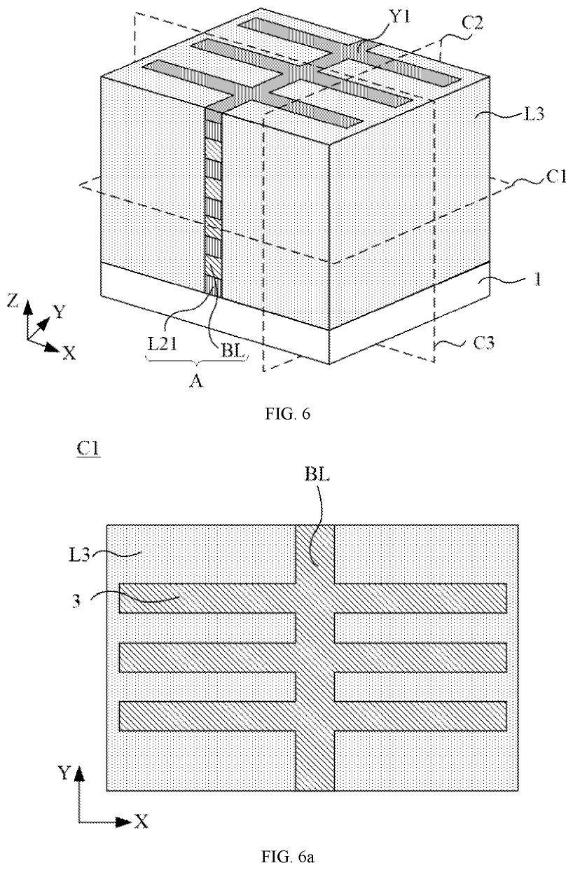

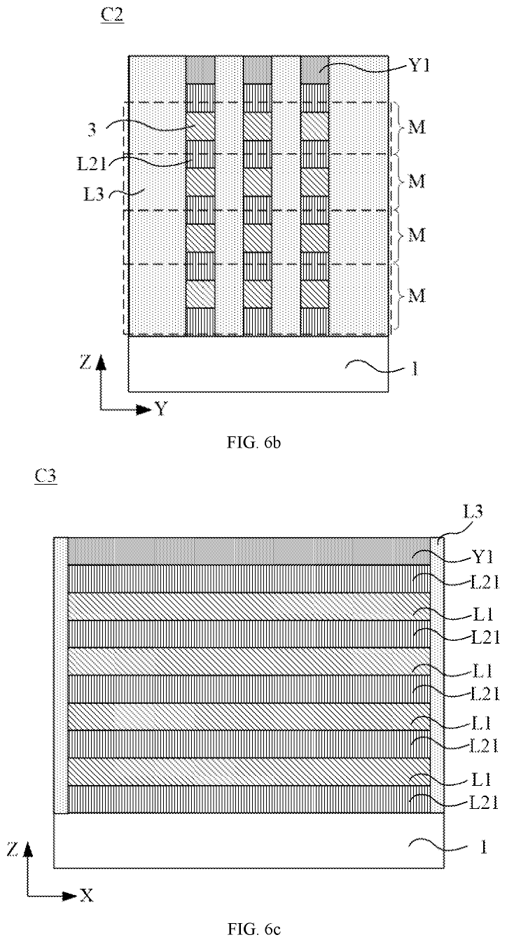

In step S20, referring to FIG. 6, FIG. 6a, FIG. 6b, and FIG. 6c, one etching process is performed on the plurality of conductive film layers L1 and the plurality of first sacrificial layers L21 to form a bit line BL and a plurality of conductive units 30 that are integrally connected to the bit line BL and spaced apart in the first direction (e.g., Y direction) in the conductive film layers L1, so as to obtain an initial stacked structure A.

Exemplarily, the conductive film layer L1 and the first sacrificial layer L21 in the initial stacked structure A are etched based on the pattern of the first mask layer Y1 to have the same pattern, which is, for example, as shown in FIG. 6a. The patterned conductive film layer L1 includes the bit line BL extending in a column direction (e.g., Y direction) and the plurality of conductive units 3 extending in the bit line BL. The conductive units 3 extend in the X direction and are spaced apart in the Y direction. Furthermore, optionally, the conductive units 3 are symmetrically distributed with respect to the bit line BL.

Referring to FIG. 6, FIG. 6a, FIG. 6b, and FIG. 6c, after the initial stacked structure A is obtained, an isolation layer L3 covering a sidewall of the initial stacked structure A and filling a space between adjacent conductive units 3 is formed.

Exemplarily, the material of the isolation layer L3 includes, but is not limited to, oxide, such as silicon oxide.

Exemplarily, the isolation layer L3 is formed by a deposition process, and an outline dimension of the isolation layer L3 can be determined to match the initial stacked structure A and the subsequent arrangement positions of the capacitors 4.

It should be noted that, in some embodiments, the isolation layer L3 may be formed before removing the above first mask layer Y1. In this way, after the isolation layer L3 is formed, the first mask layer Y1 may be removed by a grinding process, and it is ensured that surfaces of the isolation layer L3 and the top first sacrificial layer L21 are flat. The grinding process includes but is not limited to chemical mechanical polishing (CMP).

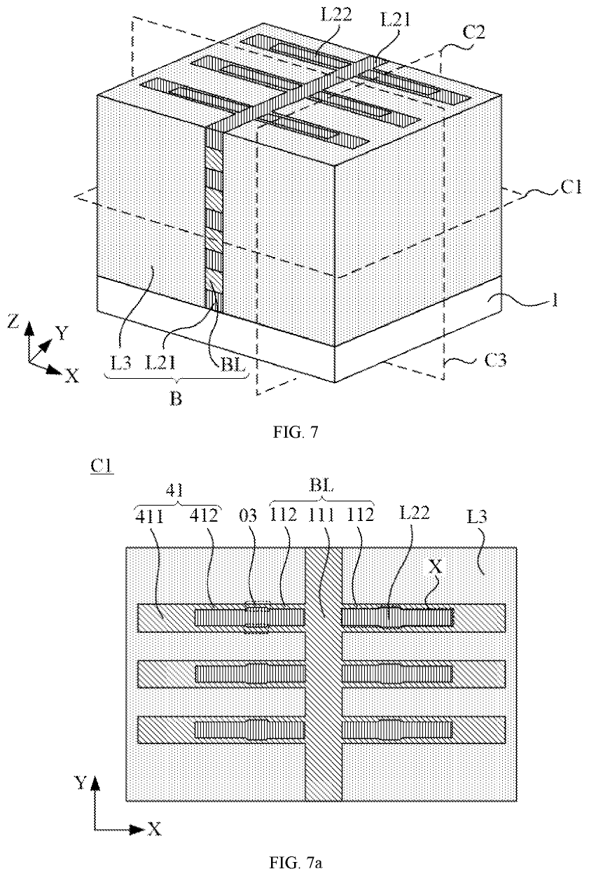

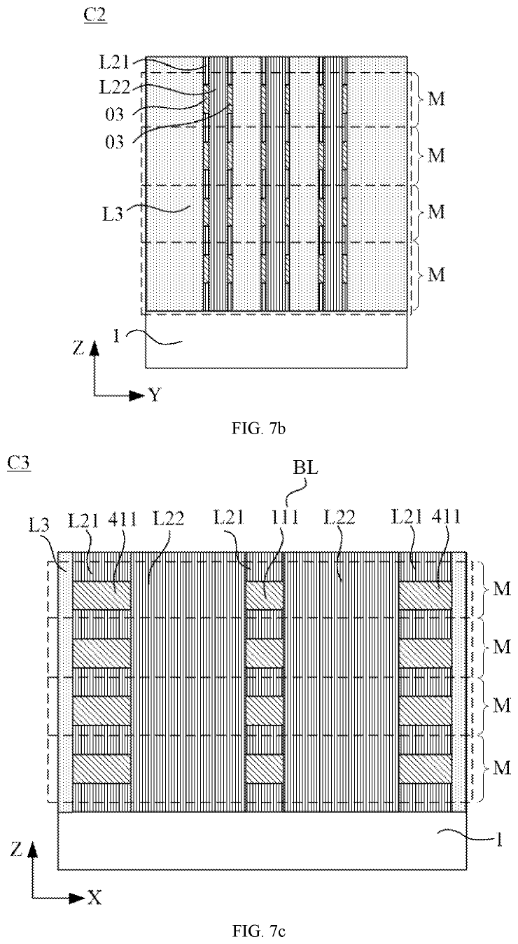

Referring to FIG. 7, FIG. 7a, FIG. 7b, and FIG. 7c, one etching process is performed on the initial stacked structure A to form a sacrificial trench X at an end of each conductive unit 3 close to the bit line BL, and obtain first branches 112 of the bit line BL, a first electrode 41 and to-be-removed portions 03 between the first branches 112 and the first electrode 4. The first branches 112, the first electrode 41 and the to-be-removed portions 03 are located around the sacrificial trench X.

The first electrode 41 includes a first electrode body 411 and two second branches 412. The to-be-removed portions 03 are each located between the corresponding first branch 112 and the second branch 412 and connected to the corresponding first branch 112 and the second branch 412, and are each configured to define a formation position of a sub-film layer 211 in the semiconductor layer 21.

Exemplarily, as shown in FIG. 7a, an orthographic projection of the sacrificial trench X on the substrate 1 is in a strip shape, and a size of the corresponding region in the sacrificial trench X for forming the portion to be removed 03 in the first direction (e.g., Y direction) is greater than a size of other regions in the sacrificial trench X in the first direction (e.g., Y direction).

Referring to FIG. 7, FIG. 7a, FIG. 7b, and FIG. 7c, a second sacrificial layer L22 is filled in the sacrificial trench X to obtain a stacked structure B.

After the second sacrificial layer L22 is filled in the sacrificial trench X by using a deposition process, an upper surface of the stacked structure B may be polished by using a CMP process. The stacked structure B includes the patterned conductive film layers L1 and the first sacrificial layers L21, as well as the isolation layer L3 disposed on the sidewall of the initial stacked structure A and the second sacrificial layer L22 filled in the sacrificial trench X.

Exemplarily, the material of the second sacrificial layer L22 is the same as that of the first sacrificial layer L21. The second sacrificial layer L22 includes, but is not limited to, a silicon nitride layer. Based on this, the second sacrificial layer L22 and the first sacrificial layer L21 may be etched by using the same process subsequently.

It can be understood that the second sacrificial layer L22 here is the sacrificial material correspondingly filled in the region between the first electrode body 411, the two second branches 412, the two first branches 112 and the bit line body 111 in the step S301.

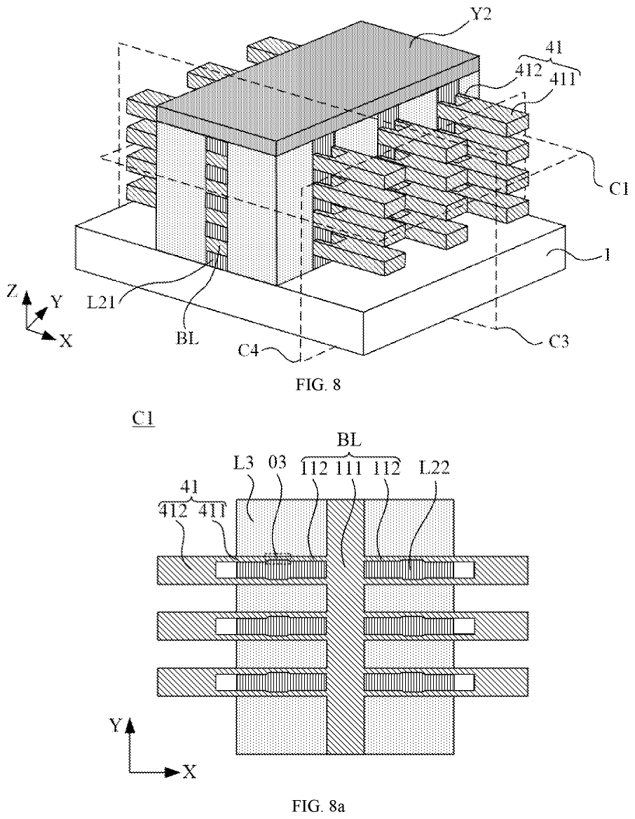

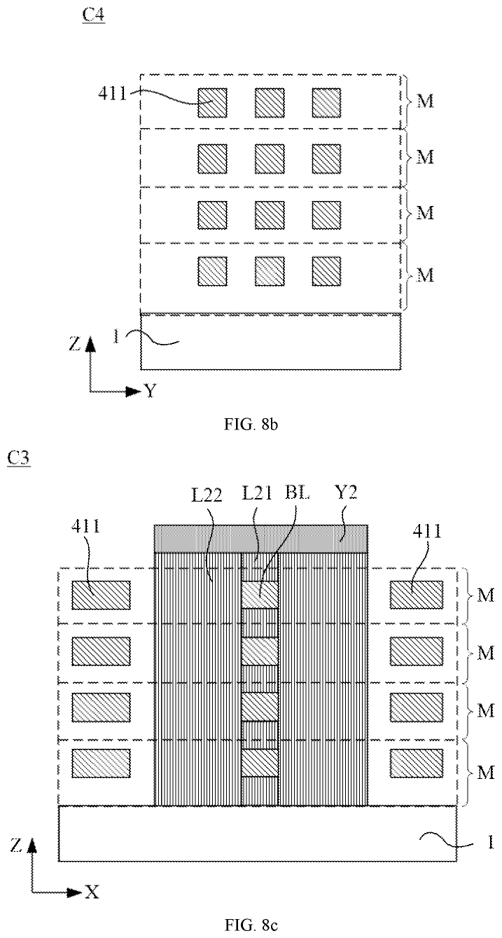

In step S60, referring to FIG. 8, FIG. 8a, FIG. 8b, and FIG. 8c, a second mask layer Y2 is formed on an upper surface of the stacked structure B. The second mask layer Y2 has an opening pattern for defining a formation position of the capacitor 4.

One etching process is performed on the stacked structure B based on the second mask layer Y2 to remove the isolation layer L3, the second sacrificial layer L22 and the first sacrificial layer L21 exposed by the opening pattern, and to expose the first electrode 41 (including the first electrode body 411 and a part of the second branch 412).

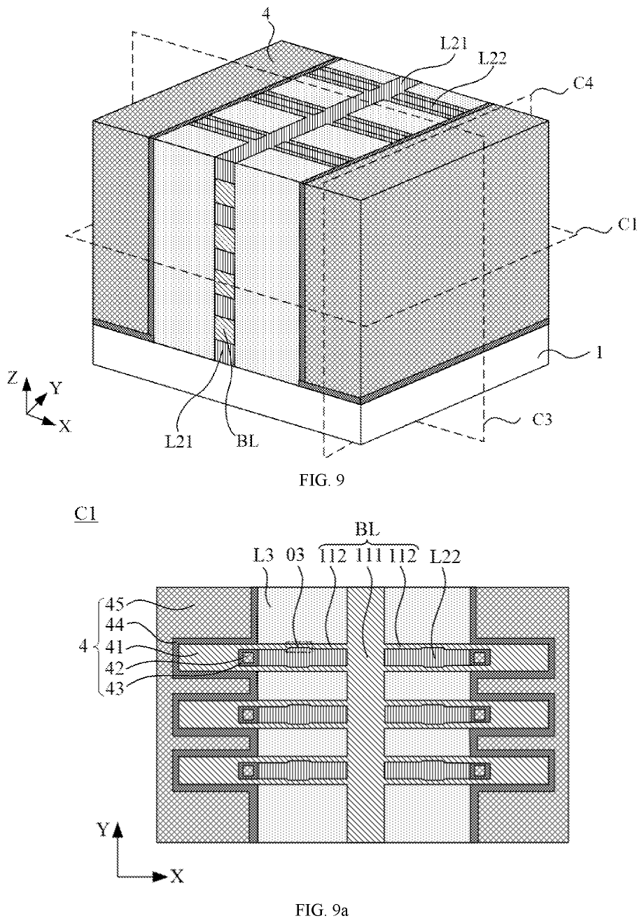

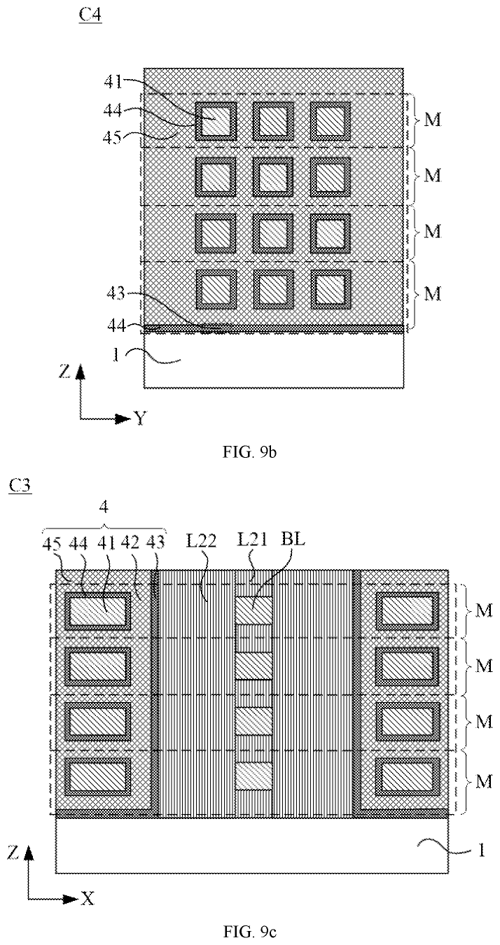

In step S601, referring to FIG. 9, FIG. 9a, FIG. 9b, and FIG. 9c, a dielectric material is deposited to form a first dielectric layer 43 conformally covering an inner surface of the first electrode 41 and an etched surface of the second sacrificial layer L22, and a second dielectric layer 44 conformally covering an outer surface of the first electrode 41.

The first dielectric layer 43 covering the inner surface of the first electrode 41 and the second dielectric layer 44 covering the outer surface of the first electrode 41 are connected as a whole.

Exemplarily, the first dielectric layer 43 and the second dielectric layer 44 may be formed simultaneously by using a deposition process. The material of the first dielectric layer 43 and the second dielectric layer 44 includes a HK dielectric material. A deposition thickness of the first dielectric layer 43 and a deposition thickness of the second dielectric layer 44 can be set according to requirements.

Exemplarily, as shown in FIG. 9a, in the same memory layer M, a plurality of second dielectric layers 44 of a column of capacitors 4 arranged in the first direction (e.g., Y direction) may be connected as a whole, and a plurality of third electrodes 45 of the column of capacitors 4 may be connected as a whole. Furthermore, the second dielectric layer 44 extends to be located on an etched surface of the isolation layer L3 (i.e., a sidewall of the third insulating layer 33).

Exemplarily, as shown in FIG. 9c, in different memory layers M, the first dielectric layers 43 of the capacitors 4 arranged adjacent to each other in the direction perpendicular to the substrate 1 (e.g., Z direction) are connected as a whole. Optionally, as shown in FIG. 9c, in the memory layer M adjacent to the substrate 1, the first dielectric layer 43 and the second dielectric layer 44 further extend to cover a surface of the substrate 1.

In step S602, referring to FIG. 9, FIG. 9a, FIG. 9b, and FIG. 9c, a conductive material is deposited to form a second electrode 42 covering the first dielectric layer 43, and a third electrode 45 covering the second dielectric layer 44, and the third electrode 45 is connected to the second electrode 42.

Exemplarily, the material of the second electrode 42 and the third electrode 45 includes, but is not limited to, polysilicon.

Exemplarily, after the third electrode 45 is formed by using a deposition process, an upper surface of the third electrode 45 may be polished by using a CMP process.

Exemplarily, as shown in FIG. 9a, in the same memory layer M, the plurality of third electrodes 45 of the column of capacitors 4 may be connected as a whole. As shown in FIG. 9b, in different memory layers M, a plurality of third electrodes 45 of capacitors 4 located on the same side of the bit line BL may be connected as a whole.

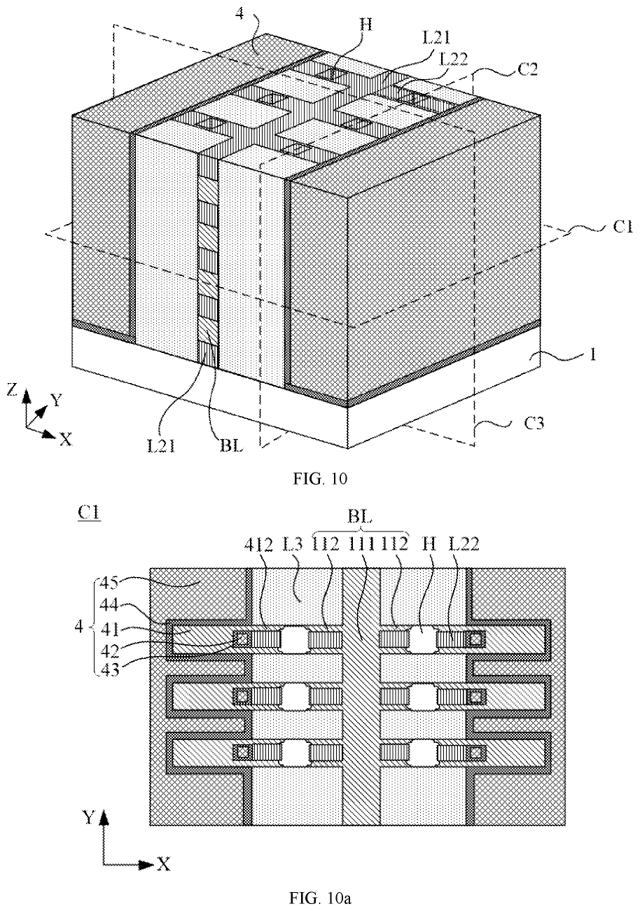

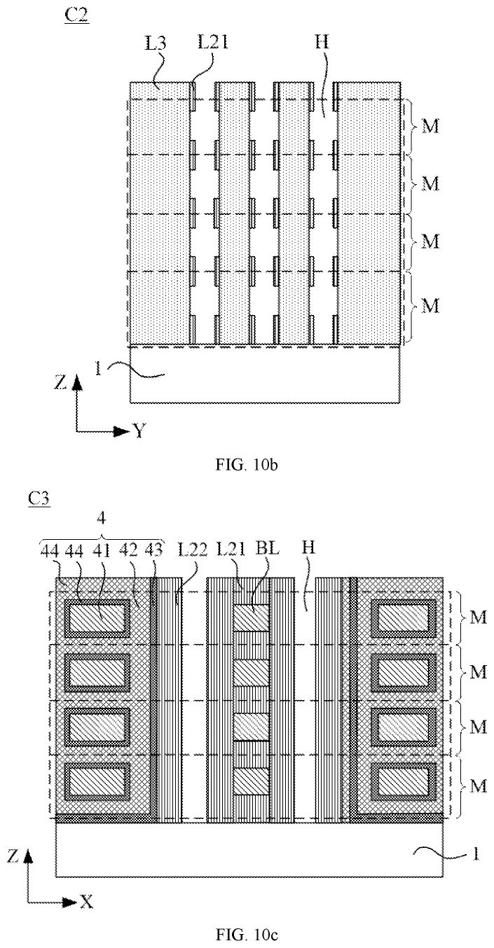

As described above, after the capacitors 4 are formed, in the step S302, referring to FIG. 10, FIG. 10a, FIG. 10b, and FIG. 10c, the second sacrificial layer L22 is etched to remove a part of the sacrificial material, thereby forming a receiving hole H. The receiving hole H is configured to define a formation region of the transistors 2 and the word line WL.

It can be understood that the portion to be removed 03 described in some of the above embodiments can be removed in this step to expose the corresponding sidewall of the isolation layer L3. In this way, the receiving hole H is surrounded by the sidewall of the second sacrificial layer L22 and the sidewall of the isolation layer L3 exposed after etching.

Exemplarily, the step of forming the receiving hole H can be performed in two steps. In the first step, the second sacrificial layer L22 is etched to form an initial receiving hole. Exemplarily, before the second sacrificial layer L22 is etched, a mask layer (e.g., including a photoresist layer and/or a hard mask layer) may be formed on an upper surface of the corresponding structure to etch the second sacrificial layer L22 based on a mask pattern in the mask layer. In the second step, the portion to be removed 03 is removed by etching based on the initial receiving hole to form the receiving hole H.

Optionally, the portion to be removed 03 may be removed by using an isotropic etching process.

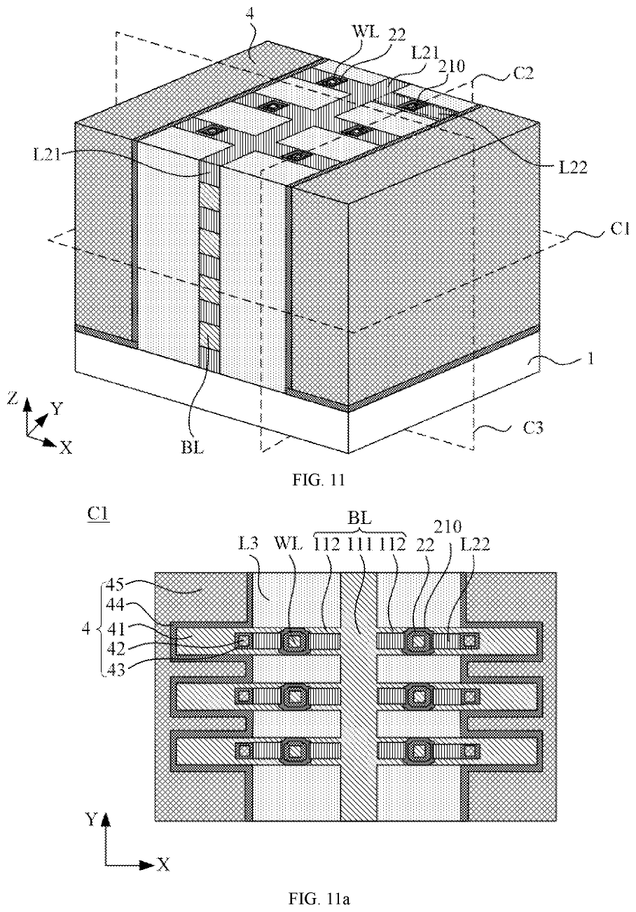

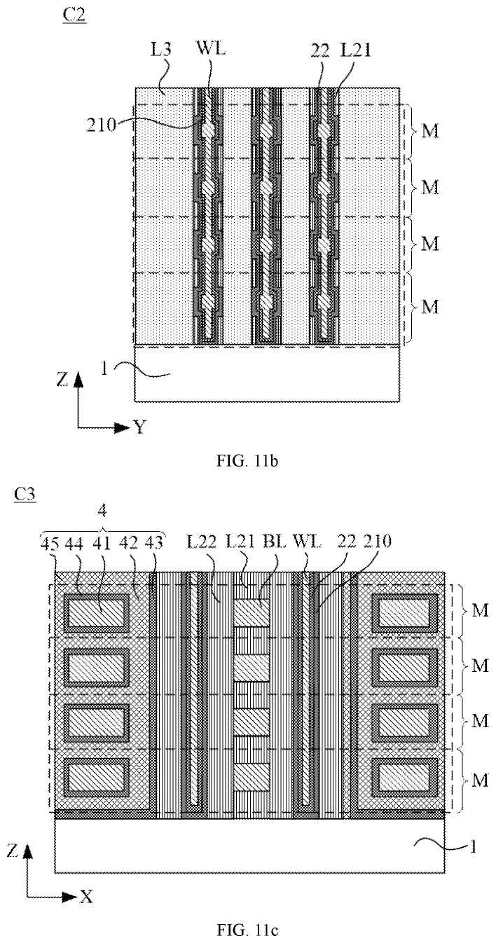

In step S303, referring to FIG. 11, FIG. 11a, FIG. 11b, and FIG. 11c, an initial semiconductor layer 210, a gate insulating layer 22, and a word line WL are sequentially formed on an inner wall of the receiving hole H.

Exemplarily, the initial semiconductor layer 210 includes but is not limited to a metal oxide semiconductor layer, such as an IGZO layer.

Exemplarily, the initial semiconductor layer 210 may be formed by using a deposition process, such as an ALD process.

Exemplarily, the gate insulating layer 22 includes but is not limited to a HK dielectric layer.

Exemplarily, the gate insulating layer 22 may be formed by using a deposition process, such as an ALD process.

Exemplarily, the word line WL extends in the direction perpendicular to the substrate 1 (e.g., Z direction), and the material of the word line WL includes but is not limited to tungsten metal.

Exemplarily, the word line WL may be formed by using a deposition process. Furthermore, after the word line WL is formed by using the deposition process, a CMP process may be used to polish an upper surface of the obtained structure, ensuring that the exposed word line WL has a good surface quality.

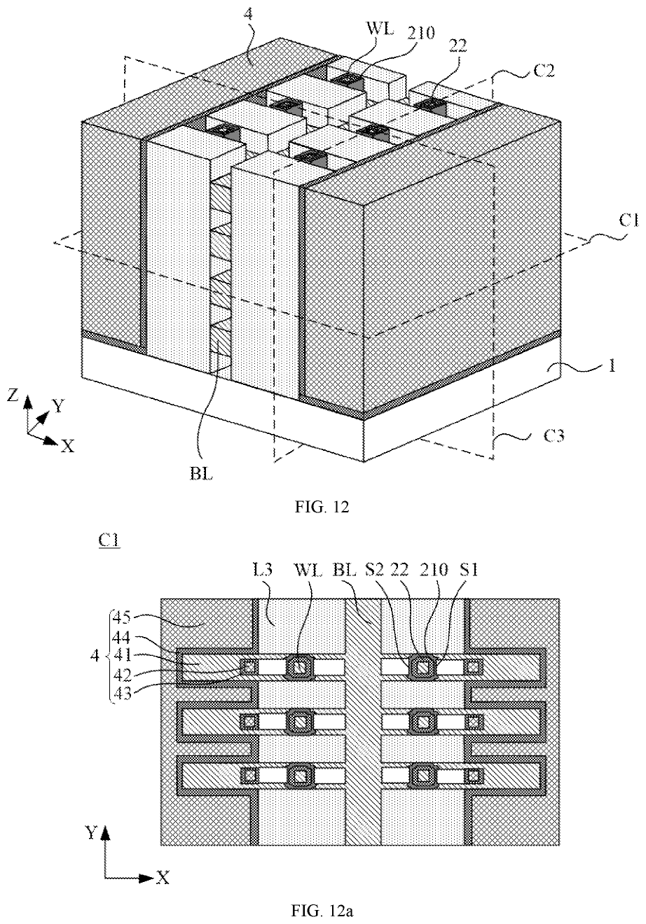

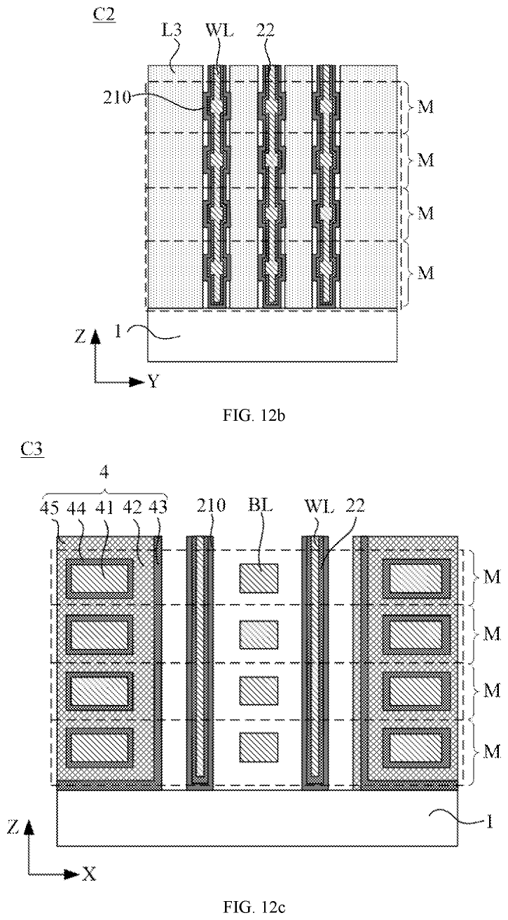

In step S304, referring to FIG. 12, FIG. 12a, FIG. 12b, and FIG. 12c, the remaining second sacrificial layer L22 and the remaining first sacrificial layer L21 are removed to expose a first sidewall S1 of the initial semiconductor layer 210 facing the first electrode 41 and a second sidewall S2 of the initial semiconductor layer 210 facing the bit line BL.

Optionally, a mask layer (e.g., including a photoresist layer and/or a hard mask layer) may be formed on an upper surface of the structure obtained after forming the word line WL to etch and remove the remaining second sacrificial layer L22 and the remaining first sacrificial layer L21 based on a mask pattern in the mask layer.

Optionally, the remaining second sacrificial layer L22 and the remaining first sacrificial layer L21 may be removed by using an isotropic etching process.

In step S305, with reference to FIGS. 12, 12a, 12b, and 12c and FIGS. 1, 1a, 1b, and 1c, it is understood that the initial semiconductor layer 210 is etched based on the first sidewall S1 and the second sidewall S2 to expose the gate insulation layer 22, and a remaining part of the initial semiconductor layer 210 in each memory layer M forms two sub-film layers 211 spaced apart in the first direction (e.g., Y direction), and two ends of each sub-film layer 211 are respectively connected to the corresponding first branch 112 and second branch 412.

Exemplarily, the initial semiconductor layer 330 may be etched by using an isotropic etching process to form the sub-film layers 211.

After the sub-film layers 211 are formed, a first receiving cavity X1 is formed between the two first branches 112 corresponding to the same transistor 2, the bit line body 111 and the gate insulating layer 22, and a second receiving cavity X2 is formed between the first electrode body 411, the two second branches 412 and the gate insulating layer 22.

In steps S40 and S50, referring to FIG. 1, FIG. 1a, FIG. 1b, and FIG. 1c, removed regions of the remaining second sacrificial layer L22 and the remaining first sacrificial layer L21, and etched regions of the initial semiconductor layer 330 are filled with an insulating material to form an insulating layer. The insulating material includes but is not limited to silicon oxide. The insulating layer includes: a first insulating layer 31 filled in the first receiving cavity X1, a second insulating layer 32 filled in the second receiving cavity X2, and a third insulating layer 33 and a fourth insulating layer 34 shown in FIG. 1b.

The insulating layer may be formed by using a deposition process. Furthermore, after the insulating layer is formed by using the deposition process, an upper surface of the insulating layer may be polished by using a CMP process, so as to ensure that the upper surface of the insulating layer is flat, and the upper surface of the word line WL is exposed and has a good surface quality.

It should be noted that the “one etching process” described in some of the above embodiments can be understood as etching based on the pattern of the same mask layer to form the same pattern, but not limited to a specific etching method. For example, the one etching process may be performed by dry etching, by wet etching, or by both dry etching and wet etching.

In summary, in some embodiments of the present disclosure, the conductive unit 3 in the conductive film layer L1 is first patterned to form the sacrificial trench X, so as to remove redundant metal that may exist between the bit line BL and the word line WL and between the word line WL and the first electrode 41 of the capacitor 4 in the conductive film layer L1. Then, the second sacrificial layer L22 is backfilled in the sacrificial trench X, and spaces for manufacturing the capacitor 4, the transistor 2 and the word line WL can be formed by patterning the second sacrificial layer L22, so as to manufacture the capacitor 4, the transistor 2 and the word line WL. Finally, the remaining second sacrificial layer L22 and the remaining first sacrificial layer L21 are replaced with the insulating layer. The embodiments of the present disclosure can have significant improvement and optimization on improving the parasitic capacitance in the memory and removing the parasitic transistor.

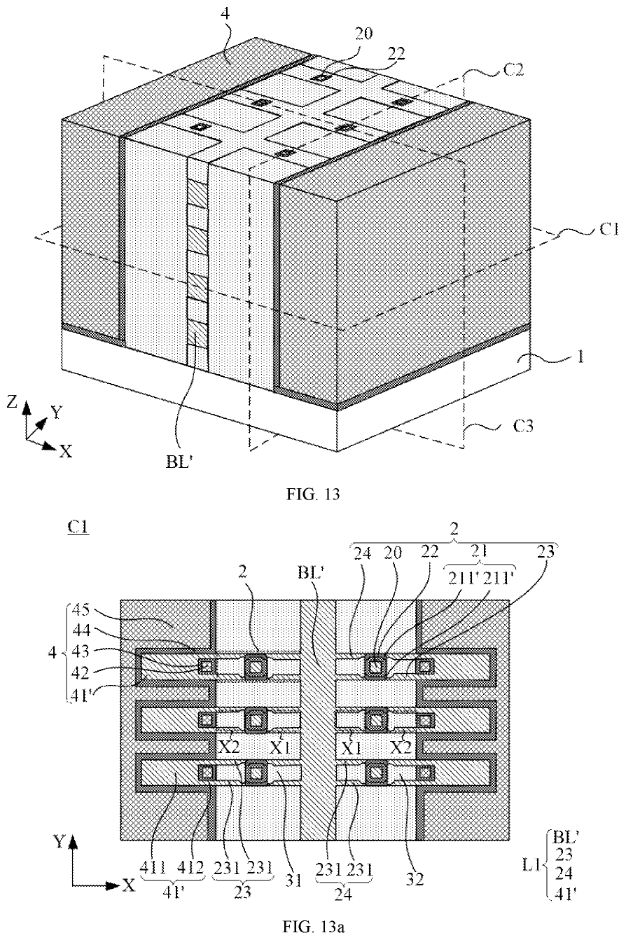

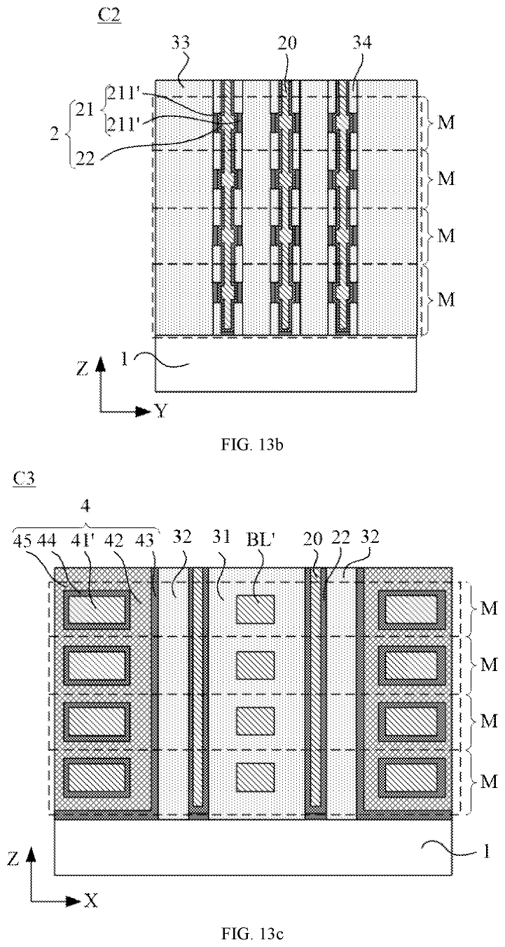

In some embodiments of the present disclosure, a memory is further provided. Referring to FIG. 13, FIG. 13a, FIG. 13b, and FIG. 13c, the memory includes a conductive film layer L1, a gate 20, a semiconductor layer 21, and a gate insulating layer 22. The conductive film layer L1 includes a bit line region BL′ extending in a column direction (e.g., Y direction), and a source region 23 and a drain region 24 sequentially distributed towards the bit line region BL′ in a row direction (e.g., X direction). The drain region 24 is connected to the bit line region BL′. The source region 23 and the drain region 24 are spaced apart. The gate 20 is located between the source region 23 and the drain region 24, and extends in a direction perpendicular to a substrate 1. The semiconductor layer 21 is arranged on a sidewall of the gate 20, for example, surrounding the sidewall of the gate 20. The gate insulating layer 22 is arranged between the sidewall of the gate 20 and the semiconductor layer 21. At least one of the source region 23 or the drain region 24 includes two third branches 231, and the two third branches 231 are each connected to the semiconductor layer 21.

The gate 20, the semiconductor layer 21, the gate insulating layer 22, the source region 23, and the drain region 24 together constitute a transistor 2.

With reference to the related description in some of the above embodiments, in some embodiments, the memory includes one or more memory layers M stacked in the direction perpendicular to the substrate 1 (e.g., Z direction). Accordingly, there are a plurality of transistors 2. The plurality of transistors 2 may be distributed in the same memory layer M. Alternatively, the plurality of transistors 2 may be distributed in different memory layers M stacked in the direction perpendicular to the substrate 1.

Exemplarily, each transistor 2 in each memory layer M may be taken as a transistor of a corresponding memory cell, and the memory cell may be of a 1T1C, 1T0C or 2T0C architecture. Taking 1T1C architecture as an example, the memory cell may include a capacitor and a transistor connected to the capacitor. Exemplarily, in a 3D-DRAM, a plurality of memory cells may be distributed in arrays in planes parallel to the substrate 1 (e.g., X-Y plane), and these arrays of memory cells are stacked periodically in the direction perpendicular to the substrate 1 (e.g., Z direction) to form multiple storage layers M.

Exemplarily, the substrate 1 may be made of semiconductor material, insulating material, conductive material or any combination of these materials. The substrate 1 may be a single-layer structure or a multi-layer structure. For example, the substrate 1 may be a silicon (Si) substrate, a silicon germanium (SiGe) substrate, a silicon germanium carbon (SiGeC) substrate, a silicon carbide (SiC) substrate, a gallium arsenide (GaAs) substrate, an indium arsenide (InAs) substrate, an indium phosphide (InP) substrate or other III/V semiconductor substrates or II/VI semiconductor substrates. Alternatively, the substrate 1 may be a layered substrate including, for example, a stack of Si and SiGe, a stack of Si and SiC, a silicon-on-insulator (SOI), or a silicon-germanium-on-insulator, or the like.

Exemplarily, the conductive film layer L1 may be a metal layer, such as a tungsten metal layer or a copper metal layer.

Exemplarily, the material of the gate 20 includes metal, such as tungsten or copper.

Exemplarily, a shape of an orthographic projection of the gate 20 on a surface of the substrate 1 includes but is not limited to a rectangle. The rectangle described here may be an ideal rectangle having sharp corners, or an approximate rectangle including an etching deviation or a transition corner.

In the above embodiment, at least one of the source regions 23 or the drain region 24 includes two third branches 231, and the two third branches 231 are each connected to the semiconductor layer 21, which may be implemented in many different ways. In the following embodiments, an example in which the source region 23 and the drain region 24 each include two third branches 231 is described, and it can be understood that it is also feasible that only one of the source regions 23 and the drain region 24 includes two third branches 231.

Exemplarily, as shown in FIG. 13a, a first receiving cavity X1 is formed between the two third branches 231 of the drain region 24, and a second receiving cavity X2 is formed between the two third branches 231 of the source region 23. The memory further includes: a first insulating layer 31 filled in the first receiving cavity X1, and a second insulating layer 32 filled in the second receiving cavity X2. Furthermore, the memory may further include other insulating layers in addition to the first insulating layer 31 and the second insulating layer 32, such as a third insulating layer 33 and a fourth insulating layer 34 in FIG. 13b, so as to meet the insulation requirement between corresponding conductive elements or between conductive elements and the outside, which will not be discussed in detail in the embodiments of the present disclosure.

In some embodiments, referring to FIG. 13a, the third branches 231 and the bit line region BL′ have a same film thickness, and the film thickness is a dimension in the direction perpendicular to the substrate 1 (e.g., Z direction).

In some embodiments, referring to FIG. 13a, the semiconductor layer 21 includes two sub-regions 211′ spaced apart, the two sub-regions 211′ extend in the row direction (e.g., X direction) on the sidewall of the gate 20, and an extended end portion of any of the two sub-regions 211′ is connected to an extended end portion of the third branch 231 of the source region 23 or the drain region 24.

The semiconductor layer 21 may at least serve as a channel layer of the transistor 2 in the corresponding memory cell.

Exemplarily, the sub-region 211′ in the semiconductor layer 21 may be a metal oxide semiconductor layer, for example, a metal oxide semiconductor material including at least one of indium, gallium, zinc or tin.

In some examples, the sub-region 211′ in the semiconductor layer 21 may be an indium gallium zinc oxide (IGZO) layer, but is not limited thereto.

In some embodiments, referring to FIG. 13a, the memory further includes a capacitor 4. The conductive film layer L1 further includes a first electrode region 41′. The first electrode region 41′, the source region 23 and the drain region 24 are sequentially distributed towards the bit line region BL′ in the row direction (e.g., X direction), and the first electrode region 41′ is connected to the source region 23.

Optionally, referring to FIG. 13a, the source region 23 includes two third branches 231. The first electrode region 41′ includes two second branches 412. The two second branches 412 are connected to the two third branches 231 of the source region 23 in a one-to-one correspondence.

It should be noted that, in some embodiments, the capacitor 4 further includes a second electrode 42 arranged between the first electrode region 41′ and the second insulating layer 32, and a first dielectric layer 43 surrounding a sidewall of the second electrode 42.

Exemplarily, a shape of an orthographic projection of the second electrode 42 on the surface of the substrate 1 includes but is not limited to a rectangle. The rectangle described here may be an ideal rectangle having sharp corners, or an approximate rectangle including an etching deviation or a transition fillet.

In some embodiments, referring to FIG. 13a and FIG. 13c, the capacitor 4 further includes a second dielectric layer 44 and a third electrode 45 stacked on an outer surface of the first electrode region 41′. The third electrode 45 is connected to the second electrode 42.

Exemplarily, the first dielectric layer 43 and the second dielectric layer 44 may be formed of a same dielectric material and by a same deposition process.

Exemplarily, the first dielectric layer 43 and the second dielectric layer 44 include, but are not limited to, HK (high-K) dielectric layers. The HK dielectric layer refers to a dielectric layer with a high dielectric constant K. The high dielectric constant K is, for example, greater than 3.9.

Exemplarily, the second electrode 42 and the third electrode 45 may be formed of a same conductive material and by a same deposition process.

Exemplarily, the second electrode 42 and the third electrode 45 include but are not limited to polysilicon.

It can be understood that the memory in the above embodiments has a similar structure to the memory in some of the afore-described embodiments, and the manufacturing method for the memory can be adaptively performed with reference to the manufacturing method for the afore-described memory, which will not be described in detail here.

Some embodiments of the present disclosure further provide an electronic device, such as a data storage device, a photocopier, a network device, a home appliance, an instrument, a mobile phone, a computer, and other devices with a data storage function. The electronic device may include a housing, a circuit board arranged in the housing, and a memory integrated on the circuit board. The structure of the memory may refer to the related description in some of the above embodiments. The electronic device may further include other necessary elements or components, which are not limited in the embodiments of the present disclosure.

In some embodiments, external control devices such as a processor or an actuator coupled to the memory may also be integrated on the circuit board. For example, the electronic device further includes a processor integrated on the circuit board. The processor is coupled to the memory, and the processor can control read and write operations of the memory.

In some embodiments, the memory is 3D-DRAM.

The technical features in the above embodiments may be combined arbitrarily. For concise description, not all possible combinations of the technical features in the above embodiments are described. However, provided that they do not conflict with each other, all combinations of the technical features are to be considered to be within the scope of protection of the present disclosure.

The above-mentioned embodiments only describe several implementations of the present disclosure, and their description is specific and detailed, but should not be understood as a limitation on the protection scope of the present disclosure. It should be noted that, for a person of ordinary skill in the art, various variations and improvements can be further made without departing from the conception of the present disclosure, and these all fall within the protection scope of the present disclosure. Therefore, the protection scope of the present disclosure should be subject to the appended claims.

1. A memory, comprising:
a substrate;
a word line extending in a direction perpendicular to the substrate;
a plurality of transistors each comprising a semiconductor layer located on a sidewall of the word line, and a gate insulating layer arranged between the sidewall of the word line and the semiconductor layer; and
a bit line comprising a bit line body, and a plurality of first branches corresponding to the plurality of transistors, respectively, the bit line body extending in a first direction parallel to the substrate, and the first branches extending towards the semiconductor layer and being connected to the semiconductor layer.

2. The memory of claim 1, wherein the bit line comprises two first branches corresponding to a same transistor, and a first receiving cavity is formed between the two first branches, the bit line body and the gate insulating layer; and
wherein the memory further comprises a first insulating layer filled in the first receiving cavity.

3. The memory of claim 2, wherein the two first branches and the bit line body are formed by patterning a single conductive film layer, each of the two first branches and the bit line body have a same film thickness, and the film thickness is a dimension in the direction perpendicular to the substrate.

4. The memory of claim 2, wherein the semiconductor layer comprises two sub-film layers extending along the sidewall of the word line, respectively, the two sub-film layers are spaced apart in the first direction, and the two sub-film layers are connected to the two first branches in a one-to-one correspondence.

5. The memory of claim 4, further comprising a capacitor,
wherein the capacitor comprises a first electrode connected to the semiconductor layer, and
wherein the first electrode comprises two second branches, and the two second branches are connected to the two sub-film layers of the semiconductor layer in a one-to-one correspondence.

6. The memory of claim 5, wherein the first electrode further comprises a first electrode body connected to the two second branches, both the first electrode body and the second branches are sequentially arranged in a second direction, the second direction is parallel to the substrate and intersects the first direction, and a second receiving cavity is formed between the first electrode body, the two second branches and the gate insulating layer; and
wherein the memory further comprises a second insulating layer filled in the second receiving cavity.

7. The memory of claim 6, wherein the capacitor further comprises a second electrode arranged between the first electrode and the second insulating layer, and a first dielectric layer surrounding a sidewall of the second electrode.

8. The memory of claim 7, wherein the capacitor further comprises a second dielectric layer and a third electrode stacked on an outer surface of the first electrode, and the third electrode is connected to the second electrode.

9. The memory according to claim 1, wherein the plurality of transistors are distributed in one layer, or distributed in different layers stacked in the direction perpendicular to the substrate.

10. A manufacturing method for a memory, the manufacturing method comprising:
forming a conductive film layer on a substrate;
patterning the conductive film layer to form a bit line, the bit line comprising a bit line body extending in a first direction parallel to the substrate, and a plurality of first branches spaced apart in the first direction; and
forming a transistor and a word line correspondingly at extended end portions of two adjacent first branches of the plurality of first branches, wherein the word line extends in a direction perpendicular to the substrate, the transistor comprises a semiconductor layer located on a sidewall of the word line and a gate insulating layer arranged between the sidewall of the word line and the semiconductor layer, and the plurality of first branches extend towards the semiconductor layer and are connected to the semiconductor layer.

11. The manufacturing method of claim 10, wherein a first receiving cavity is formed between two first branches of the plurality of first branches corresponding to a same transistor, the bit line body and the gate insulating layer, and the manufacturing method further comprises:
filling the first receiving cavity with an insulating material to form a first insulating layer.

12. The manufacturing method of claim 11, wherein the memory further comprises a capacitor comprising a first electrode, and the manufacturing method further comprises:
when patterning the conductive film layer, forming the first electrode simultaneously with the bit line, the first electrode comprising two second branches spaced apart in the first direction,
wherein the semiconductor layer is further connected to the two second branches.

13. The manufacturing method of claim 12, wherein the first electrode further comprises a first electrode body connected to the two second branches, both the first electrode body and the second branches are sequentially arranged in a second direction parallel to the substrate, a second receiving cavity is formed between the first electrode body, the two second branches and the gate insulating layer, and the manufacturing method further comprises:
filling the second receiving cavity with an insulating material to form a second insulating layer.

14. The manufacturing method of claim 13, wherein forming the transistor and the word line correspondingly at the extended end portions of the two adjacent first branches comprises:
before forming the first insulating layer and the second insulating layer, filling a sacrificial material in a region between the first electrode body, the two second branches, the two first branches, and the bit line body;
removing a part of the sacrificial material to form a receiving hole, the receiving hole being configured to define a formation region of the transistor and the word line;
forming an initial semiconductor layer, the gate insulating layer and the word line sequentially on an inner wall of the receiving hole;
removing a remaining part of the sacrificial material to expose a first sidewall of the initial semiconductor layer facing the first electrode and a second sidewall of the initial semiconductor layer facing the bit line; and
etching the initial semiconductor layer based on the first sidewall and the second sidewall until the gate insulating layer is exposed, and making a remaining part of the initial semiconductor layer form two sub-film layers spaced apart in the first direction, both ends of each sub-film layer being connected to the corresponding first branch and second branch, respectively.

15. The manufacturing method of claim 13, further comprising:
forming a second electrode and a first dielectric layer surrounding a sidewall of the second electrode between the first electrode and the second insulating layer.

16. The manufacturing method of claim 15, further comprising:
forming a second dielectric layer on an outer surface of the first electrode while forming the first dielectric layer between the first electrode and the second insulating layer; and
forming a third electrode on an outer surface of the second dielectric layer, and connecting the third electrode to the second electrode while forming the second electrode between the first electrode and the second insulating layer.

17. A memory, comprising:
a conductive film layer comprising a bit line region extending in a column direction, and a source region and a drain region sequentially distributed towards the bit line region in a row direction, the drain region being connected to the bit line region, and the source region and the drain region being spaced apart;
a gate located between the source region and the drain region, and extending in a direction perpendicular to a substrate;
a semiconductor layer arranged on a sidewall of the gate; and
a gate insulating layer arranged between the sidewall of the gate and the semiconductor layer;
wherein at least one of the source region or the drain region comprises two third branches, and the two third branches are each connected to the semiconductor layer.

18. The memory of claim 17, wherein each of two the third branches and the bit line region have a same film thickness, and the film thickness is a dimension in a direction perpendicular to the substrate.

19. The memory of claim 17, wherein the semiconductor layer comprises two sub-regions spaced apart, the two sub-regions extend in the row direction on the sidewall of the gate, and an extended end portion of any of the two sub-regions is connected to an extended end portion of the corresponding third branch of the source region or the drain region.

20. The memory of claim 17, wherein the conductive film layer further comprises a first electrode region, the first electrode region, the source region and the drain region are sequentially distributed towards the bit line region in the row direction, and the first electrode region is connected to the source region.

21. (canceled)

22. (canceled)
